(19) United States
(12) Patent Application Publication
(10) Pub. No.: US 2025/0226229 A1
(43) Pub. Date: Jul. 10, 2025

(54) Workpiece Processing Method

(71) Applicant: Lintec Corporation, Tokyo (JP)

(72) Inventors: Hayato Nakanishi, Tokyo (JP); Jun Maeda, Tokyo (JP); Hironobu Fujimoto, Tokyo (JP)

(73) Assignee: Lintec Corporation, Tokyo (JP)

(21) Appl. No.: 18/850,603

(22) PCT Filed: Mar. 2, 2023
(86) PCT No.: PCT/JP2023/007781

§ 371 Date: Sep. 25, 2024

(30) Foreign Application Priority Data
Mar. 28, 2022 (JP) 2022-051524

(51) Int. Cl. H01L 21/304; C09J 5/00; H01L 21/683; H01L 21/78

(52) U.S. Cl. CPC H01L 21/304; C09J 5/00; H01L 21/6836; H01L 21/78; C09J 2203/326; C09J 2301/502; H01L 2221/68327; H01L 2221/6834; H01L 2221/68381

(57) ABSTRACT

A processing method of a workpiece capable of reducing Total Thickness Variation (TTV) of the workpiece includes adhering a front surface protection sheet on a front surface of a workpiece having the front surface and a back surface; grinding the back surface of the workpiece on which the front surface protection sheet is adhered; wherein the front surface of the workpiece has bump electrodes, a raised pattern has been formed along an outer circumference part on the front surface of the workpiece which is an area different from an area where the bump electrodes are formed when adhering the front surface protection sheet, the front surface protection sheet is adhered on the front surface of the workpiece so as to embed the bump electrodes, and a height Hb of each of the bump electrodes and a height H1 of the raised pattern satisfy Hb/8<H1<Hb/1.5.

### TECHNICAL FIELD

The present invention relates to a processing method of a workpiece. Particularly, the present invention relates to a processing method capable of reducing TTV of the workpiece after back grinding even when bump electrodes are formed on the workpiece.

### BACKGROUND

As a method of densely mounting chips, such as semiconductor chips with circuits formed thereon, onto a substrate, a method which bonds the chips and the electrodes on the substrate via bump electrodes formed on a circuit surface of the chips is known. The bump electrode is a raised-shape electrode which protrudes in a thickness direction of the chip.

By separating a workpiece such as a wafer with the circuits formed thereon, these chips are obtained as separated workpieces. Along with rapid progress in developing compact and multifunctional electronic devices which use such chips, it is also demanded for the chips to become more compact, lower height, and higher density. In order to make even more compact and lower height chips, generally a thickness of the chip is thinned down by grinding a back surface of the wafer after the circuits are formed on a front surface of the wafer.

When performing back grinding of the wafer, a front surface protection sheet, which is called a back grinding tape, is adhered on the front surface of the wafer to protect the circuits on the front surface of the wafer and also to hold the wafer.

When the front surface protection sheet is adhered on the workpiece having the bump electrodes and the back grinding of the workpiece is carried out, because of the height difference between the bump electrode and the circuit surface, in some cases, the workpiece was damaged and insufficient adhesion between the workpiece and the front surface protection sheet occurred.

Patent Document 1 discloses a semiconductor wafer processing adhesive tape which can conform well to the semiconductor wafer surface having steps and projections, and can be released from the semiconductor wafer without causing damages or leaving adhesive residue.
[Patent Document 1] JP Patent Application Laid Open No. 2017-171896

### SUMMARY

Incidentally, circuits are not formed on an outer circumference part of a workpiece, thus, bump electrodes are also not formed. Hence, a height difference occurs between the outer circumference part of the workpiece and the area where the circuits and the bump electrodes are formed (an inner part of the workpiece).

The height difference between the outer circumference part of the workpiece and the inner part of the workpiece on the front surface of the workpiece will appear as a height difference of the front surface protection sheet when it is adhered on the front surface of the workpiece. That is, in a thickness direction of the workpiece, the height of the front surface protection sheet becomes low at the area corresponding to the outer circumference part of the workpiece, and the height of the front surface protection sheet becomes high at the area corresponding to the inner part of the workpiece.

For back grinding, usually, the surface to which the front surface protection sheet of the workpiece has been adhered is placed on a grinding table such as a chuck table or so, and then, it is fixed by suction. Here, the height of the front surface protection sheet at the area corresponding to the outer circumference area of the workpiece is lower than the height of the front surface protection sheet at the area corresponding to the inner part. Therefore, when the workpiece is placed on the grinding table, the outer circumference part of the workpiece is not sufficiently in contact with the grinding table, and thus spaces are formed between each other.

When suction is performed under such condition, the outer circumference part of the workpiece is pulled down together with the front surface protection sheet towards the grinding table, and then, it is fixed to the grinding table. Then, back grinding is carried out. When the suction is released after the back grinding is completed, the outer circumference part of the workpiece is also released and warps from the grinding table. During back grinding, the back surface of the workpiece is ground almost to the same height, however, if the outer circumference part of the workpiece warps, the thickness of the outer circumference part of the work piece becomes thicker than the inner part of the workpiece as much as the outer circumference part has pulled down. The difference between the height of the outer circumference part of the workpiece and the height of the inner part of the workpiece is reflected on TTV (Total Thickness Variation) of the workpiece, and TTV of the workpiece tends to become large. When TTV of the workpiece becomes larger, it is easier for the workpiece to crack, which may cause problems when separating the workpiece, therefore, TTV of the workpiece is preferably small.

Patent Document 1 does not consider the above-mentioned problem, thus, even if the semiconductor wafer processing adhesive tape of Patent Document 1 is adhered on the semiconductor with the bump electrodes formed, the height difference exists between the inner part of the semiconductor wafer and the outer circumference part of the semiconductor wafer. As a result, there was a problem of increased TTV of the semiconductor wafer after back grinding.

The present invention is achieved in view of such circumstances, and the object is to provide a processing method of workpiece which can reduce TTV of the workpiece.

### Means for Solving the Problems

Embodiments of the present invention are as described in below.

[1] A processing method, including:
adhering a front surface protection sheet on a front surface of a workpiece having the front surface and a back surface;
grinding the back surface of the workpiece on which the front surface protection sheet is adhered;
wherein the front surface of the workpiece has bump electrodes,
a raised pattern has been formed along an outer circumference part on the front surface of the workpiece which is an area different from an area where the bump electrodes are formed when adhering the front surface protection sheet,
the front surface protection sheet is adhered on the front surface of the workpiece so as to embed the bump electrodes, and
a height Hb of each of the bump electrodes and a height H1 of the raised pattern satisfy Hb/8<H1<Hb/1.5.

[2] The processing method according to [1], wherein the raised pattern is configured of a resin.

[3] The processing method according to [1] or [2], wherein the area different from the area where the bump electrodes are formed includes an area where the raised pattern is not formed.

[4] The processing method according to any one of [1] to [3], wherein the raised pattern is formed by taking space from an outer edge of the workpiece.

[5] The processing method according to any one of [1] to [4], wherein the front surface protection sheet has a configuration that a base, an intermediate layer, and an adhesive layer are stacked in this order.

[6] The processing method according to [5], wherein a shear storage modulus at 65° C. of the intermediate layer is 0.5 MPa or less.

[7] The processing method according to [5] or [6], wherein a loss tangent at 65° C. of the intermediate layer is greater than 0.5.

[8] The processing method according to any one of [1] to [7] further comprising:
releasing the front surface protection sheet from the front surface after the back surface is ground;
wherein at least part of the raised pattern is released from the front surface of the workpiece when the front surface protection sheet is released.

[9] The processing method according to any one of [1] to [8] further comprising:
forming a groove on the front surface of the workpiece before adhering the front surface protection sheet on the front surface of the workpiece;
wherein the workpiece is separated into a plurality of separated workpieces using the groove as a starting point while grinding the back surface of the workpiece.

[10] The processing method according to any one [1] to [8] further comprising:
forming a modified area in the workpiece before grinding the back surface of the workpiece;
wherein the workpiece is separated into a plurality of separated workpieces using the modified area as a starting point while grinding the back surface of the workpiece.

### Effect of the Invention

According to the present invention, a processing method of a workpiece capable of reducing TTV of the workpiece can be provided.

### BRIEF DESCRIPTION OF DRAWINGS

FIG. 1 shows schematic images of cross sections in (A) to (E) which explain how TTV of a workpiece increases when the workpiece is processed using a conventional method.

FIG. 2A is a schematic plan view of a workpiece with bump electrodes and a raised pattern on an outer circumference part when a processing method of the workpiece according to the present embodiment is used.

FIG. 2B is a schematic cross section along IIA-IIA line shown in FIG. 2A.

FIG. 3 is a schematic cross section showing another example of positions forming a raised pattern on the workpiece.

FIG. 4A is a schematic cross section of a front surface protection sheet which is preferably used for the processing method of the workpiece according to the present embodiment.

FIG. 4B is a schematic cross section showing another example of the front surface protection sheet used preferably for the processing method of the workpiece according to the present embodiment.

FIG. 5 shows schematic cross sections in (A) to (C) which explain how TTV of the workpiece can be reduced when the workpiece is processed using the method according to the present embodiment.

### DETAILED DESCRIPTION

Hereinbelow, the present invention is explained in detail using the figures based on the specific embodiments. First, main terms used in the present specification are explained.

A workpiece means a plate-shaped body to which a front surface protection sheet is adhered, and then separated. The workpiece may be a wafer of a circle shape (note that, this includes a wafer having orientation flat), a strip to which a square shape panel package and a resin sealing have been performed (a strip-shaped substrate), etc. Among these, a wafer is preferable as the effect of the present invention can be readily achieved. As the wafer, for example, it may be a semiconductor wafer such as a silicon wafer, a gallium arsenide wafer, a silicon carbide wafer, a gallium nitride wafer, an indium phosphide wafer; an insulator wafer such as a glass wafer, a lithium tantalate wafer, or a lithium niobate wafer; and may also be a reconstituted wafer which is made of a resin and a semiconductor used for making fan-out packages and the like. Among these, as a wafer, a semiconductor wafer or an insulation wafer is preferable as the effect of the present invention can be achieved readily, and even more preferably it is a semiconductor wafer.

The separation of workpiece means that the workpiece is divided into each circuit to obtain separated workpieces. For example, in the case that the workpiece is a wafer, the separated workpieces are chips; and in the case that the workpiece is a strip (strip-shaped substrate) to which panel level packaging or mold resin sealing is performed, the separated workpieces are semiconductor packages.

A front surface of the workpiece is a surface at the side where circuits, electrodes, etc., are formed. A back surface of the workpiece is a surface at the side where circuits are not formed.

The bump electrodes are formed on the front surface of the workpiece, and these project out in a thickness direction of the workpiece. Usually, a plurality of bump electrodes is formed on one circuit (the separated workpiece). Also, the cross-section shape in the thickness direction of the bump electrode may be a columnar shape, a cone shape, a circular shape, etc., and the tip of the bump electrode usually has a round shape.

DBG refers to a method which forms grooves with a predetermined depth on the front surface side of the wafer, and then grinds from the back surface side of the wafer, and thereby, dicing the wafer by grinding. The grooves formed on the front surface side of the wafer may be formed using a method such as blade dicing, laser dicing, plasma dicing, etc.

Also, LDBG is a modified example of DBG, and it is a method which provides a modified area in the wafer using a laser, and dicing the wafer using stress of wafer back grinding.

A group of separated workpieces is a plurality of separated workpieces held on the front surface protection sheet after the workpiece is separated. The group of separated workpieces as a whole form the similar shape as the shape of the workpiece. Also, a group of chips is a plurality of chips held on the front surface protection sheet which is obtained after the wafer as the workpiece is separated. These chips as a whole form the similar shape as the shape of the wafer.

In the specification, “(meth)acrylate” is used to represent both “acrylate” and “methacrylate”, and the same applies to other similar terms.

In the specification, “energy ray” refers to ultraviolet ray, electron beam, etc., and preferably it is ultraviolet ray.

Unless mentioned otherwise, “weight average molecular weight” is a polystyrene conversion value measured using a gel permeation chromatography (GPC) method. Measurements by such method are carried out using, for example, a high-speed GPC apparatus “HLC-8120GPC” manufactured by Tosoh Corporation. In this apparatus the following columns are connected in the order of “TSK guard column H_{XL}-H”, “TSK Gel GMH_{XL}”, and “TSK Gel G2000 H_{XL}” (which are all products of Tosoh Corporation.). The measurements are performed under the conditions of a column temperature at 40° C. and a flow rate at 1.0 mL/min, and a differential refractometer is used as a detector.

A releasing sheet is a sheet supporting the adhesive layer in a releasable manner from the adhesive layer. Here, the sheet does not necessarily limit the thickness, and it is used as a concept which includes a film.

A mass ratio used for the explanation regarding compositions such as an adhesive agent composition is based on active ingredients, and unless mentioned otherwise, a solvent is not included.

### (1. Processing Method of Workpiece)

As one example of processing of the workpiece to which circuits or so are formed on one surface (front surface) and the other surface (back surface) does not have the circuits or so, the back surface of the workpiece may be ground (back grinding). By grinding the back surface, the workpiece can be separated, and the separated workpieces can be thinned down.

The front surface of the workpiece may be formed with the bump electrodes in addition to the circuits in order to electrically connect the circuits of the substrate etc.

As mentioned in above, the bump electrodes are formed by projecting in a thickness direction of the workpiece. Therefore, there is a height difference between the tips of the bump electrodes and the area on the workpiece where the bump electrodes are not formed. The area where the bump electrodes are not formed roughly coincides with the area where the circuits are not formed, hence, the area where the bump electrodes are not formed exists on the outer circumference part of the workpiece.

Before back grinding of the workpiece is performed, the front surface protection sheet is adhered on the front surface of the workpiece in order to protect the circuits, etc., formed on the front surface of the workpiece. In order to protect the bump electrodes, which are projecting from the front surface, from the pressure applied while back grinding, it is necessary that the bump electrodes are sufficiently fixed using the front surface protection sheet.

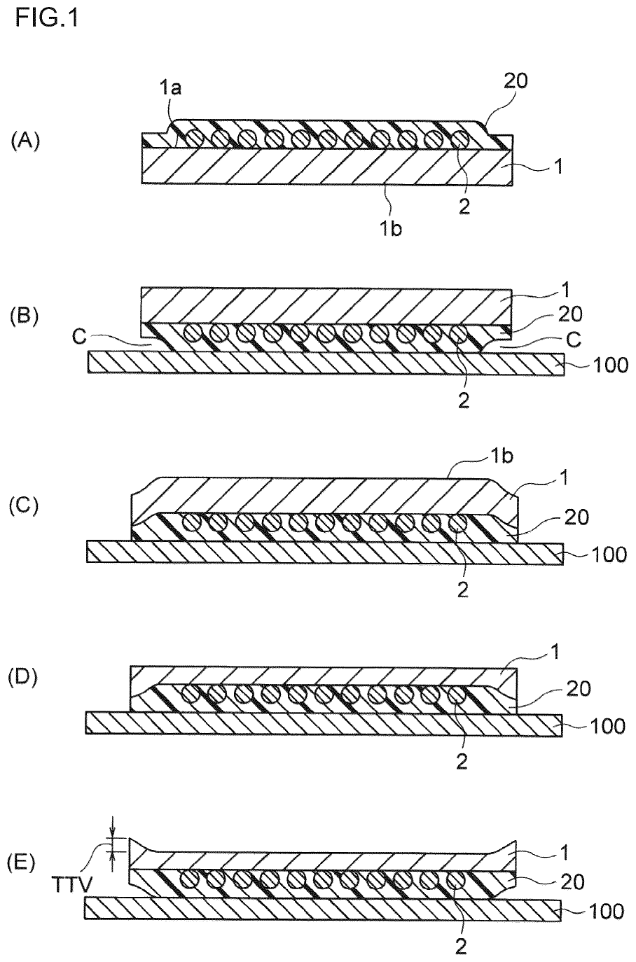

As shown in FIG. 1(A), in the case that a front surface protection sheet 20 is adhered on a circuit surface (front surface 1a) where bump electrodes 2 are formed, the front surface protection sheet 20 adhered on the front surface 1a of the workpiece conforms the shape of the front surface 1a of a workpiece and the bump electrodes 2, hence, the height difference will also appear on the front surface protection sheet 20 as it reflects the height difference on the workpiece 1.

When back grinding of the workpiece is performed while the height difference exists on the workpiece, as shown in FIG. 1(B), the front surface side of the workpiece, that is, the front surface protection sheet 20 is placed on a chuck table 100 so that these are contacting with each other, and for example, the workpiece 1 and the front surface protection sheet 20 are fixed to the chuck table 100 by suction. At this time, when the workpiece 1 is placed on the chuck table 100, the front surface protection sheet 20 on the bump electrodes 2 contacts the chuck table 100. However, the front surface protection sheet 20 on the outer circumference part of the workpiece 1, that is the area where the bump electrodes are not formed, is not thoroughly contacting the chuck table 100 when the workpiece 1 is placed on the chuck table 1 due to the above-mentioned height difference, or there may be a space C between the chuck table 100 and the front surface protection sheet 20.

When suction is carried out under such condition, as shown in FIG. 1(C), the front surface protection sheet 20 on the outer circumference part of the workpiece 1 deforms due to suction, and the front surface protection sheet 20 is pulled down and fixed to the chuck table 100. The outer circumference part of the workpiece 1 is adhered to the front surface protection sheet 20, and thus, the outer circumference part of the workpiece 1 also deforms along with the deformation of the front surface protection sheet 20. That is, the outer circumference part of the workpiece 1 is fixed at the position closer to the chuck table 100 than the inner part of the workpiece 1 (the area where the bump electrodes 2 are formed).

After the workpiece 1 and the front surface protection sheet 20 are fixed to the chuck table 100, a back surface 1b of the workpiece 1 is ground. FIG. 1(D) shows the workpiece after it has been ground. As the back surface of the workpiece is ground to about the same height, as shown in FIG. 1(D), the thickness of the outer circumference part of the workpiece 1 is thicker than the thickness of the inner part of the workpiece 1 by the amount which has been fixed closer to the chuck table 100. As a result, when suction is released, as shown in FIG. 1(E), the deformation of the front surface protection sheet 20 is also released, and the height difference between the inner part of the workpiece 1 and the outer circumference part of the workpiece 1 becomes apparent. Therefore, in this case, the thickness of the outer circumference part of the workpiece 1 tends to be the maximum thickness of the workpiece 1 and the thickness at the inner part of the workpiece 1 tends to be the minimum thickness of the workpiece 1.

The difference between the maximum thickness of the workpiece and the minimum thickness of the workpiece is called TTV (Total Thickness Variation), and the above-mentioned thickness difference causes TTV to become larger. If TTV becomes larger, it may cause problems such as the workpiece tends to break easily, and trouble during separation of the workpiece.

The present inventors have found that by using a below-described method, the above-mentioned thickness difference can be reduced, and as a result, the present inventors have found that a workpiece with small TTV can be obtained. In below, a processing method of a workpiece according to the present embodiment is described in detail.

The processing method of the workpiece according to the present embodiment at least includes the below-described two steps.

Step 1: adhering the front surface protection sheet on the front surface of the workpiece having the front surface and a back surface.

Step 2: grinding the back surface of the workpiece to which the front surface protection sheet has been adhered.

In below, the processing method of the workpiece is described using the case where the workpiece is a wafer and the separated workpieces are chips.

### (1.1. Step 1)

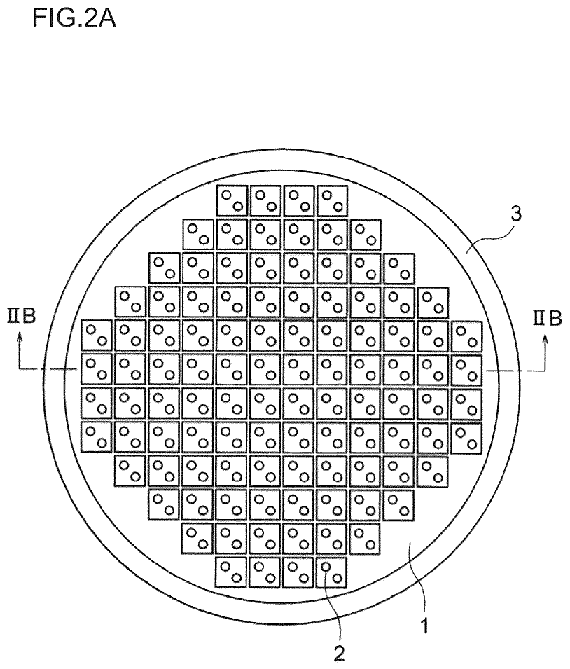

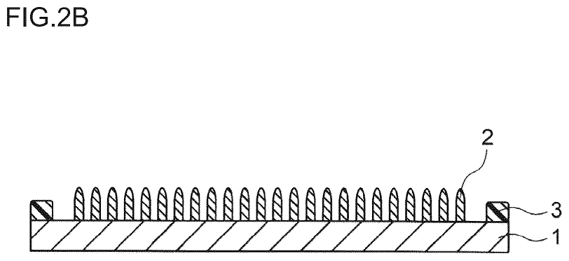

In Step 1, the front surface protection sheet is adhered on the front surface of the wafer. In the present embodiment, prior to adhering the front surface protection sheet, as shown in FIG. 2A and FIG. 2B, a raised pattern 3 is formed (Step A) on an area (the outer circumference part of the wafer) which is at outside of the area where the bump electrodes 2 are formed along the radial direction of the wafer 1. That is, Step A is performed before Step 1.

### (1.2. Raised Pattern)

The raised pattern 3 is a pattern formed on the front surface of the wafer 1 and it projects in the thickness direction of the wafer 1. By forming such raised pattern 3 on the area where the bump electrodes 2 are not formed, when a front surface protection sheet 10 is adhered on the front surface of the wafer 1, the part corresponding to the raised pattern 3 is also raised in addition to the part corresponding to the area where the bump electrodes 2 are formed. As a result, the height difference between the area where the bump electrodes 2 are formed (the inner part of the wafer) and the area where the bump electrodes 2 are not formed (the outer circumference part of the wafer) is reduced. Therefore, TTV of the wafer 1 during back grinding can be reduced.

In the present embodiment, the height of the raised pattern is set according to the height of the bump electrode. Specifically, when the height of the raised pattern is H1 and the height of the bump electrode is Hb, Hb/8<H1<Hb/1.5 is satisfied, and preferably Hb/6<H1<Hb/1.3 is satisfied.

In the case that H1 is out of the range of the above-mentioned relations, TTV of the wafer after back grinding tends to become large.

### (1.2.1. Shear Storage Modulus of Raised Pattern)

In the present embodiment, the shear storage modulus at 23° C. of the raised pattern is preferably 50 MPa or higher. When the shear storage modulus at 23° C. of the raised pattern is within the above-mentioned range, the raised pattern tends to become relatively hard, and even when performing back grinding, the height difference between the outer circumference part of the wafer and the inner part of the wafer is reduced.

A material configuring the raised pattern only needs to be a material which can achieve the above-mentioned effects. In the present embodiment, as it is easy to form the raised pattern, the material configuring the raised pattern is preferably a resin, and preferably the shear storage modulus at 23° C. is within the above-mentioned range. As the resin, it is preferably an adhesive resin which can adhere on the front surface of the wafer. For example, the adhesive resin may be an acrylic resin, a silicone resin, a urethane resin, an epoxy resin, a phenolic resin, a urea resin, an alkyd resin, a vinyl acetate resin, a vinyl chloride resin, an amide resin, an imide resin, a chloroprene rubber, a nitrile rubber, a styrene butadiene rubber, nylon, polycarbonate, polypropylene, etc.

Also, the adhesive resin is preferably a curable resin. Such resin can be easily formed into a predetermined shape before curing; and after curing, it can prevent abrasives, cooling water, or so from entering into the circuit surface of the wafer. Further, it is easy to become a hard material which can reduce the height difference between the inner part and outer circumference part of the wafer. Note that, in the case that the material configuring the raised pattern is a curable resin, the shear storage modulus at 23° C. of the raised pattern is the shear storage modulus after curing.

Examples of the curable resin include a heat curable resin, an energy ray-curable resin, etc., and considering the fact that the raised pattern is removed from the front surface of the wafer after back grinding, the curable resin is preferably an energy-ray curable resin. Specific examples of the curable resin include a combination of urethane acrylate, polymerizable monomers, and photopolymerization initiator which are mentioned later as an intermediate layer composition.

The raised pattern is not particularly limited and it may be various patterned shapes as long as the above-mentioned effects can be achieved. For example, as shown in FIG. 2A, the raised pattern may be a ring form which includes an outer edge of the wafer. Such raised pattern can be easily formed, and also the above-mentioned effects can be assured.

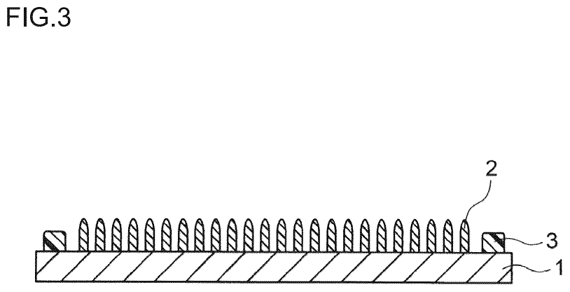

Also, as shown in FIG. 3, the raised pattern may be formed by taking space from the outer edge of the wafer towards inside in a radial direction. When the front surface protection sheet is released, such raised pattern allows a pickup tape to cover the entire surface of the raised pattern, hence, it is advantageous because the raised pattern can also be released together. Also, the raised pattern shown in FIG. 2A is a continuous pattern, however, it may be a discontinuous pattern.

Note that, the raised pattern can be formed to the entire area where the bump electrodes are not formed, however, considering that a large amount of material will be necessary for forming such raised pattern, and the possibility that the material of the raised pattern may adhere on the bump electrodes and the circuits, preferably the raised pattern is formed while taking space from the bump electrodes. In other words, the area where the bump electrodes are not formed preferably includes the area where the raised pattern is not formed.

A means for forming the raised pattern may be determined based on the materials used for forming the raised pattern. For example, in the case that the raised pattern is formed using the curable resin, a means for coating the liquid resin before curing can be used. Specifically, coating devices such as a die coater, a curtain coater, a spray coater, a slit coater, a knife coater, etc.; printing devices such as screen printing, inkjet printing, etc.; and dripping devices such as a dispenser etc., may be mentioned.

### (1.3. Front Surface Protection Sheet)

After the raised pattern is formed (after Step A), the front surface protection sheet is adhered on the front surface of the wafer. In the present embodiment, the front surface protection sheet is adhered so that at least the bump electrodes on the front surface of the wafer are embedded. Here, “so that the bump electrodes on the front surface of the wafer are embedded” means that the front surface protection sheet is adhered without forming space between the front surface protection sheet and the bump electrodes. Note that, the raised pattern may be embedded in the front surface protection sheet, or part of the raised pattern may not be embedded in the front surface protection sheet and the raised pattern may be partially exposed.

By embedding the bump electrodes in the front surface protection sheet, the bump electrodes are fixed by the front surface protection sheet, and during back grinding, even when outside force is applied on the bump electrodes, damages to the bump electrodes can be reduced. Further, by embedding the bump electrodes in the front surface protection sheet, it reduces the height difference formed in the inner part of the workpiece. Therefore, TTV of the wafer as a whole can be reduced.

The front surface protection sheet only needs to be configured so that the bump electrodes are embedded when it is adhered on the front surface of the wafer. In the present embodiment, the front surface protection sheet is preferably configured by stacking the base and the adhesive layer. The adhesive layer is adhered on the front surface of the wafer and the bump electrodes are embedded in the adhesive layer.

In order to securely embed the bump electrodes in the front surface protection sheet, it is more preferable that the base, the intermediate layer, and the adhesive layer are stacked in this order. The intermediate layer can sufficiently conform, together with the adhesive layer, to the shape of the bump electrodes formed on the front surface of the workpiece, and the bump electrodes can be embedded into the adhesive layer and the intermediate layer. As a result, even in the case that the workpiece is ground extremely thin and force is applied on the bump electrodes etc., the adhesive layer and the intermediate layer can securely protect the bump electrodes etc. Also, in the case that the bump electrodes etc., penetrate the adhesive layer, the bump electrodes are embedded in and protected by the intermediate layer.

In below, the front surface protection sheet having a configuration that the base, the intermediate layer, and the adhesive layer are stacked in this order is explained in detail.

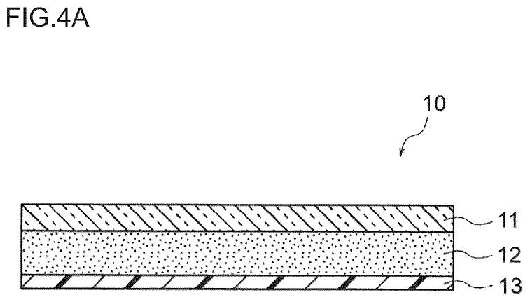

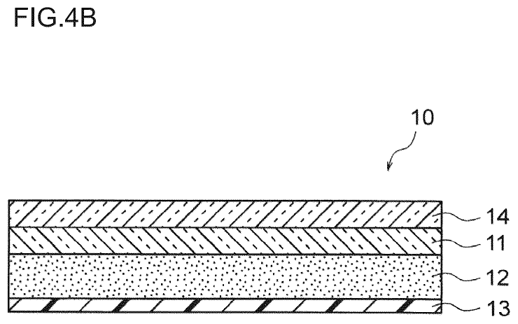

FIG. 4A shows a front surface protection sheet 10 having a configuration that an intermediate layer 12 and an adhesive layer 13 are stacked on a base 11 in this order.

The front surface protection sheet 10 is not limited to the configuration shown in FIG. 4A, and as long as the effects of the present disclosure can be obtained, other layers may be added. That is, as long as the base 11, the intermediate layer 12, and the adhesive layer 13 are stacked in this order, for example, another layer may be formed between the base 11 and the intermediate layer 12, or another layer may be formed between the intermediate layer 12 and the adhesive layer 13.

In below, configurational elements of the front surface protection sheet 10 shown in FIG. 4A is described in detail.

### (1.3.1. Base)

A base is a member which gives rigidity to the front surface protection sheet. The base is not particularly limited as long as it is configured of a material which can support the workpiece. For example, various resin films which are used for the base of back grinding tape can be used. By using such resin films, even when the workpiece becomes thinner by back grinding, the workpiece can be held without any damages. The base may be configured of a single layer film made of one resin film, or it may be configured of a plurality of films which a plurality of resin films is stacked.

### (1.3.1.1. Material of Base)

In the present embodiment, examples of the material of the base include polyesters such as polyethylene terephthalate, polyethylene naphthalate, polybutylene terephthalate, wholly aromatic polyesters, etc.; polyamide, polycarbonate, polyacetal, modified polyphenylene oxide, polyphenylene sulfide, polysulfone, polyether ketone, biaxially oriented polypropylene, etc. Among these, preferably, polyesters are used, and polyethylene terephthalate is more preferable.

A thickness of the base has influence on the rigidity of the front surface protection sheet, hence, the thickness may be set depending on the material of the base. In the present embodiment, the thickness of the base is preferably within a range between 25 μm or thicker and 200 μm or thinner, more preferably within a range between 35 μm or thicker and 150 μm or thinner, and even more preferably within a range between 40 μm or thicker and 150 μm or thinner.

At least one of main planes of the base may be carried out with adhesive treatments such as a corona treatment etc., in order to enhance the adhesion with a layer formed on the main plane. Also, at least one of the main planes may be formed with an easy-adhesion layer in order to enhance the adhesion with the layer formed on the main plane.

### (1.3.2. Intermediate Layer)

As shown in FIG. 1A, the intermediate layer 12 is placed between the base 11 and the adhesive layer 13. In the present embodiment, the intermediate layer may be configured of one layer (single layer), or it may be configured of a plurality of two or more layers.

The thickness of the intermediate layer may be determined considering the height of the bump electrode of the semiconductor wafer. In the present embodiment, the thickness of the intermediate layer is preferably within a range between 50 μm or thicker and 600 μm or thinner, and more preferably within a range between 150 μm or thicker and 500 μm or thinner. Note that, the thickness of the intermediate layer refers to a thickness of the entire intermediate layer. For example, the thickness of the intermediate layer configured of a plurality of layers refers to a total thickness of all the layers configuring the intermediate layer.

In the present embodiment, the intermediate layer has below described physical properties.

### (1.3.2.1. Shear Storage Modulus at 65° C.)

In the present embodiment, the shear storage modulus (G′) at 65° C. of the intermediate layer is preferably 0.5 MPa or less. The shear storage modulus (G′) is one indicator showing how easily the intermediate layer can deform (hardness). By having the shear storage modulus (G′) at 65° C. of the intermediate layer with the above-mentioned range, the bump electrodes can be sufficiently embedded, and the damages to the bump electrodes during back grinding can be reduced.

The shear storage modulus at 65° C. of the intermediate layer is more preferably 0.4 MPa or less, and eve more preferably it is 0.2 MPa or less. Also, the shear storage modulus at 65° C. of the intermediate layer is preferably 0.005 MPa or more from the point of suppressing the components of the intermediate layer bleeding out while the protection sheet is being stored.

The shear storage modulus at 65° C. of the intermediate layer may be measured using any known methods. For example, the intermediate layer is formed into a sample having a predetermined size, and strain is applied on the sample under a predetermined temperature range and a predetermined frequency using a dynamic mechanical analyzer to measure elasticity. From the measured elasticity, the shear storage modulus can be calculated.

### (1.3.2.2. Loss Tangent at 65° C.)

In the present embodiment, a loss tangent (tan δ) at 65° C. of the intermediate layer is preferably greater than 0.5. A loss tangent is defined by “loss modulus/storage modulus”, and it is a value measured by a response to stress applied on the target using a dynamic mechanical analyzer. When the loss tangent at 65° C. of the intermediate layer is within the above-mentioned range, the bump electrodes can be embedded sufficiently, and the damage to the bump electrodes can be reduced during back grinding.

The loss tangent at 65° C. of the intermediate layer is preferably 0.7 or greater, and more preferably 1.0 or greater. Also, the loss tangent at 65° C. of the intermediate layer is preferably 2.0 or less.

As similar to the shear storage modulus, the loss tangent at 65° C. of the intermediate layer may be measured using any known methods. For example, the intermediate layer is formed into a sample having a predetermined size, and strain is applied on the sample under a predetermined temperature range and a predetermined frequency using a dynamic mechanical analyzer to measure elasticity. From the measured elasticity, the loss tangent can be calculated.

### (1.3.3. Intermediate Layer Composition)

As long as the intermediate layer has the above-mentioned physical properties, compositions of the intermediate layer are not limited, and in the present embodiment, the intermediate layer is preferably configured of the compositions including a resin (intermediate layer composition). The intermediate layer composition preferably includes the below-listed components.

(1.3.3.1. Urethane (meth)acrylate)

Urethane (meth)acrylate is a compound at least having a (meth)acryloyl group and a urethane bond, and it can be polymerized by energy rays. In the present embodiment, urethane (meth)acrylate gives flexibility to the intermediate layer, and it is a component which enables the bump electrodes to be sufficiently embedded and fixed.

Urethane (meth)acrylate may be a monofunctional type or it may be a multifunctional type. In the present embodiment, multifunctional urethane (meth)acrylate is preferable; and from the point of embedding the bump electrodes sufficiently, bifunctional urethane (meth)acrylate is preferable.

Urethane (meth)acrylate may be an oligomer, a polymer, or it may be a mixture of these. In the present embodiment, urethane (meth)acrylate oligomer is preferable.

For example, urethane (meth)acrylate can be obtained by reacting an isocyanate-terminated urethane prepolymer, which is obtained by reacting a polyol compound with a polyvalent isocyanate compound, with (meth)acrylate containing a hydroxyl group. Note that, one type of urethane (meth)acrylate may be used, or two or more types may be used together.

A content ratio of urethane (meth)acrylate in the intermediate layer composition is preferably 20 mass % or more, more preferably 25 mass % or more, and further preferably 30 mass % or more. The content ratio of urethane (meth)acrylate in the intermediate layer composition is preferably 70 mass % or less, more preferably 65 mass % or less, and further preferably 50 mass % or less.

### (1.3.3.2. Polymerizable Monomer)

A polymerizable monomer is a polymerizable compound other than the above-mentioned urethane (meth)acrylate, and it is a compound capable of polymerizing with other components by energy ray irradiation. In the present embodiment, the polymerizable monomer is a compound including one reactive unsaturated double bond.

Examples of the polymerizable monomer include (meth)acrylate containing an alkyl group with 1 to 30 carbon atoms; (meth)acrylate containing a functional group such as a hydroxyl group, an amide group, an amino group, an epoxy group, etc.; (meth)acrylate containing an alicyclic structure; (meth)acrylate containing an aromatic structure; (meth)acrylate containing a heterocyclic structure; vinyl compounds such as styrene, hydroxyethyl vinyl ether, hydroxybutyl vinyl ether, N-vinylformamide, N-vinylpyrrolidone, and N-vinylcaprolactam, etc.

Examples of (meth)acrylate containing an alkyl group with 1 to 30 carbon atoms include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, n-pentyl (meth)acrylate, n-hexyl (meth)acrylate, 2-ethylhexyl (meth)acrylate, n-octyl (meth)acrylate, nonyl (meth)acrylate, decyl (meth)acrylate, undecyl (meth)acrylate, dodecyl (meth)acrylate, tridecyl (meth)acrylate, tetradecyl (meth)acrylate, hexadecyl (meth)acrylate, octadecyl (meth)acrylate, and eicosyl (meth)acrylate.

Examples of (meth)acrylate containing a functional group include, hydroxyl group-containing (meth)acrylate such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, etc.; an amide group-containing compound such as (meth)acrylamide, N,N-dimethyl (meth)acrylamide, N-butyl (meth)acrylamide, N-methylol (meth)acrylamide, N-methylolpropane (meth)acrylamide, N-methoxymethyl (meth)acrylamide, N-butoxymethyl (meth)acrylamide, etc; amino group-containing (meth)acrylate such as primary amino group-containing (meth)acrylate, secondary amino group-containing (meth)acrylate, tertiary amino group-containing (meth)acrylate etc.; epoxy group-containing (meth)acrylate such as glycidyl (meth)acrylate, methyl glycidyl (meth)acrylate, allyl glycidyl ether, etc.

Examples of (meth)acrylate containing an alicyclic structure include isobornyl (meth)acrylate, dicyclopentenyl (meth)acrylate, dicyclopentanyl (meth)acrylate, dicyclopentenyloxy (meth)acrylate, cyclohexyl (meth)acrylate, trimethylcyclohexyl (meth)acrylate, and adamantan (meth)acrylate.

Examples of (meth)acrylate containing an aromatic structure include phenylhydroxypropyl (meth)acrylate, benzyl (meth)acrylate, and 2-hydroxy-3-phenoxypropyl (meth)acrylate.

Examples of (meth)acrylate containing a heterocyclic structure include tetrahydrofurfuryl (meth)acrylate and morpholine (meth)acrylate.

In the present embodiment, the polymerizable monomer preferably includes (meth)acrylate containing an alkyl group with 1 to 30 carbon atoms and (meth)acrylate containing an alicyclic structure. From the point of embedding the bump electrodes sufficiently, (meth)acrylate containing an alkyl group with 4 to 14 carbon atoms is preferable, and as (meth)acrylate containing an alicyclic structure, isobornyl (meth)acrylate and trimethylcyclohexyl (meth)acrylate are preferable.

Note that, in the case that the crosslinking agent is included in the intermediate layer composition, (meth)acrylate containing a functional group which can react with the crosslinking agent is not preferable. This is, because the crosslinked structure formed due to the crosslinking reaction may possibly increase the shear storage modulus of the intermediate layer. For example, the intermediate layer composition including a combination of a polyisocyanate-based crosslinking agent and (meth)acrylate containing a hydroxyl group is not preferable.

The content ratio of polymerizable monomer in the intermediate layer composition is preferably 20 mass % or more, and more preferably 30 mas % or more. Also, the content ratio of polymerizable monomer in the intermediate layer composition is preferably 80 mass % or less, and more preferably 70 mass % or less.

Also, a mass proportion of urethane (meth)acrylate to the polymerizable monomer (urethane (meth)acrylate/polymerizable monomer) in 100 parts by mass of total of urethane (meth)acrylate and the polymerizable monomer is preferably within a range between 20/80 and 80/20, and more preferably within a range between 30/70 and 70/30.

### (1.3.3.3. Photopolymerization Initiator)

In the case that the intermediate layer composition includes the above-mentioned urethane (meth)acrylate and polymerizable monomer, the intermediate layer composition preferably includes a photopolymerization initiator. By including the photopolymerization initiator, polymerization progresses securely, and the intermediate layer with the above-mentioned properties can be obtained easily.

Examples of the photopolymerization initiator include a photopolymerization initiator such as a benzoin compound, an acetophenone compound, an acyl phosphine oxide compound, a titanocene compound, a thioxanthone compound, a peroxide compound, etc.; and a photosensitizer such as amine, quinone, etc. Specific examples may include 1-hydroxycyclohexyl phenyl ketone, 2-hydroxy-2-methyl-1-phenyl-propan-1-one, benzoin, benzoin methyl ether, benzoin ethyl ether, benzoin isopropyl ether, 2,2-dimethoxy-1,2-diphenyl ethane-1-one. One of these photopolymerization initiators may be used, or two or more may be combined for use.

With respect to total of 100 parts by mass of urethane (meth)acrylate and polymerizable monomer, a blending amount of the photopolymerization initiator is preferably within a range between 0.05 parts by mass or more and 15 parts by mass or less, and more preferably within a range between 0.5 parts by mass and 10 parts by mass or less.

### (1.3.3.4. Chain Transfer Agent)

The intermediate layer composition preferably includes a chain transfer agent. The chain transfer agent can initiate a chain transfer reaction, and it can adjust the progress of the curing reaction of the intermediate layer composition. By including the chain transfer agent, a component with short molecular chain can relatively remain even after curing, and thus, the cured polymer has a relatively flexible crosslinking structure. As a result, the shear storage modulus of the intermediate layer can easily be in the above-mentioned range.

Examples of the chain transfer agent include a thiol group-containing compound. Examples of the thiol group-containing compound include nonyl mercaptan, 1-dodecanethiol, 1,2-ethanedithiol, 1,3-propanedithiol, triazine thiol, triazine dithiol, triazine trithiol, 1,2,3-propanetrithiol, tetraethylene glycol bis(3-mercaptopropionate), trimethylolpropane tris(3-mercaptopropionate), pentaerythritol tetrakis(3-mercaptopropionate), pentaerythritol tetrakisthioglycolate, dipentaerythritol hexakis(3-mercaptopropionate), tris[(3-mercaptopropionyloxy)-ethyl]-isocyanurate, 1,4-bis(3-mercaptobutylyloxy)butane, pentaerythritol tetrakis(3-mercaptobutylate), and 1,3,5-tris(3-mercaptobutylyloxyethyl)-1,3,5-triazine-2,4,6-(1H,3H,5H)-trione. One type of the chain transfer agent may be used, or two or more may be used together.

A blending amount of the chain transfer agent is preferably within a range between 0.1 parts by mass or more and 10 parts by mass or less, and more preferably within a range between 0.3 parts by mass or more and 5 parts by mass or less, with respect to 100 parts by mass of a total of urethane (meth)acrylate and the polymerizable monomer.

### (1.3.4. Adhesive Layer)

The adhesive layer is adhered on the front surface of the workpiece (the surface where the circuits and the bump electrodes are formed), and the adhesive layer protects the front surface and supports the workpiece until it is released from the front surface. In the present embodiment, the adhesive layer, together with the intermediate layer, conforms the shapes of the bump electrodes formed on the front surface of the workpiece, and enables the bump electrodes to be sufficiently embedded into the front surface protection sheet. As a result, even when force is applied on the bump electrodes or so as the workpiece is being ground extremely thin, the front surface protection sheet can sufficiently protect the bump electrodes, etc. Further, even when the workpiece is separated into a plurality of pieces, the separated workpieces are limited from contacting each other. Also, the adhesive layer may be configured on one layer (single layer), or it may be configured of two or more layers.

A thickness of the adhesive layer is not particularly limited as long as the workpiece can be sufficiently supported. In the present embodiment, the thickness of the adhesive layer is preferably within a range between 1 μm or thicker and 100 μm or thinner, and more preferably within a range between 5 μm or thicker and 50 μm or thinner. Note that, the thickness of the adhesive layer refers to a thickness of the adhesive layer as a whole. For example, a thickness of an adhesive layer configured of a plurality of layers is a total thickness of all layers configuring the adhesive layer.

Compositions of the adhesive layer are not particularly limited as long as the adhesiveness which can protect the front surface of the workpiece can be maintained. In the present embodiment, for example, preferably the adhesive layer is configured of, an acrylic adhesive agent, an urethane adhesive agent, a rubber-based adhesive agent, a silicone-based adhesive agent, etc.

Also, the adhesive layer is preferably formed by an energy ray-curable adhesive agent. By forming the adhesive layer of the front surface protection sheet using the energy ray-curable adhesive agent, it will adhere with strong adhesive force when adhering on the workpiece, and when it is released from the workpiece, the adhesive force can be weakened by energy-ray irradiation. Therefore, when the front surface protection sheet is released while protecting the circuits etc., on the workpiece, for example, the circuits on the front surface of the workpiece are protected from breaking, the adhesive agent on the workpiece is prevented from transferring on the workpiece.

In the present embodiment, the energy ray-curable adhesive agent is preferably constituted of adhesive agent compositions including an acrylic adhesive agent. As the acrylic adhesive agent, preferably an acrylic polymer is used.

The acrylic adhesive agent is not particularly limited and any known acrylic polymers can be used, and in the present embodiment, a functional group-containing acrylic polymer is preferable. The functional group-containing acrylic polymer may be a homopolymer formed of one type of acrylic monomer, it may be a copolymer made of a plurality of types of acrylic monomers, or it may be a copolymer made of one type or plurality of types of acrylic monomers and a monomer other than acrylic monomers.

In the present embodiment, the functional group-containing acrylic polymer is preferably an acrylic copolymer obtained by copolymerizing alkyl (meth)acrylate and a functional group-containing monomer.

Examples of alkyl (meth)acrylates include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, n-pentyl (meth)acrylate, n-hexyl (meth)acrylate, 2-ethylhexyl (meth)acrylate, isooctyl (meth)acrylate, n-octyl (meth)acrylate, etc.

The functional group-containing monomer is a monomer containing a reactive functional group. The reactive functional group is a functional group capable of reacting with other compounds such as a crosslinking agent or so which are described later. Examples of the functional group contained in the functional group-containing monomer include a hydroxyl group, a carboxy group, and an epoxy group; and a hydroxyl group is preferable among these.

Examples of the hydroxyl group-containing monomer include hydroxyalkyl (meth)acrylate such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, etc.; and non-(meth)acrylic unsaturated alcohol (unsaturated alcohol not having (meth)acryloyl backbone) such a vinyl alcohol, allyl alcohol, etc.

The adhesive agent composition preferably further includes an energy ray-curable compound which include an energy ray-curable group. As the energy ray-curable compound, a compound containing one or two or more selected from the group consisting of an isocyanate group, an epoxy group, and a carboxy group is preferable; and a compound containing an isocyanate group is more preferable.

Examples of the isocyanate group-containing compound include 2-methacryloyloxyethyl isocyanate, meta-isopropenyl-α,α-dimethylbenzyl isocyanate, methacryloyl isocyanate, allyl isocyanate, 1,1-(bisacryloyloxymethyl)ethyl isocyanate; an acryloyl monoisocyanate compound obtained from reaction between a diisocyanate compound or a polyisocyanate compound with hydroxyethyl (meth)acrylate; and an acryloyl monoisocyanate compound obtained from reaction between a diisocyanate compound or a polyisocyanate compound with a polyol compound and hydroxylethyl (meth)acrylate. An isocyanate group under goes addition reaction with a hydroxyl group of the functional group-containing acrylic polymer.

The adhesive agent composition preferably further includes a crosslinking agent. For example, the crosslinking agent reacts with the functional group and crosslinks the resins included in the functional group-containing acrylic polymer.

Examples of the crosslinking agent include an isocyanate-based crosslinking agent (a crosslinking agent containing an isocyanate group) such as toluene diisocyanate, hexamethylene diisocyanate, xylylene diisocyanate, and adducts of these diisocyanates; an epoxy-based crosslinking agent (a crosslinking agents containing a glycidyl group) such as ethylene glycol glycidyl ether; an aziridine-based crosslinking agent (a crosslinking agents containing an aziridinyl group) such as hexa [1-(2-methyl)-aziridinyl]triphosphatriazine; a metal chelate-based crosslinking agent (a crosslinking agent containing a metal chelate structure) such as aluminum chelate; an isocyanurate-based crosslinking agent (a crosslinking agent containing an isocyanurate structure).

The isocyanate-based crosslinking agent is preferable as the crosslinking agent, from the point of enhancing the adhesive force of the adhesive layer by enhancing a cohesion force of the adhesive agent, and also from the point of easy availability.

The adhesive agent composition may further include a photopolymerization initiator. By including the photopolymerization initiator in the adhesive agent composition, curing reaction proceeds sufficiently even when relatively low energy ray such as ultraviolet ray is irradiated.

Examples of the photopolymerization initiator include a photoinitiator such as a benzoin compound, an acetophenone compound, an acylphosphine oxide compound, a titanocene compound, a thioxanthone compound, a peroxide compound, etc.; and a photosensitizer such as amine, quinone, etc. Specific examples include α-hydroxy cyclohexyl phenyl ketone, benzoin, benzoin methyl ether, benzoin ethyl ether, benzoin isopropyl ether, benzyl diphenyl sulfide, benzyl dimethyl ketal, tetramethylthiuram monosulfide, azobisisobutyronitrile, β-chloroanthraquinone, 2,4,6-trimethylbenzoyl-diphenylphosphine oxide, etc.

### (1.4. Production of Front Surface Protection Sheet)

The front surface protection sheet can be produced by a known method. For example, first, the above-mentioned intermediate layer composition and the adhesive agent composition are prepared. Next, using a coating method, the prepared compositions are coated on the surface of the releasing sheet, the base, etc., and then a drying treatment, a curing treatment, etc., are carried out. Thereby, the front surface protection sheet with a predetermined configuration can be obtained.

### (1.5. Step 2)

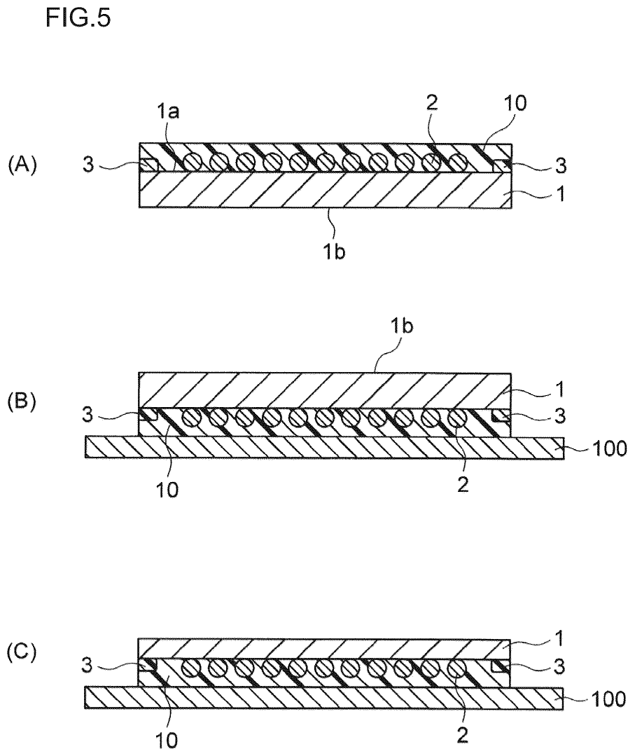

As shown in FIG. 5(A), the raised pattern is formed on the front surface of the workpiece, and the front surface protection sheet is adhered on the front surface of the workpiece. Then, the back surface of the workpiece is ground.

As shown in FIG. 5(B), the workpiece 1 to which the front surface protection sheet 10 has been adhered is placed on the chuck table 100 from the front surface side. The chuck table 100 has, for example, a porous holding surface, and due to suction from the opposite side to the side where the workpiece 1 is placed on, the front surface protection sheet 10 is suctioned and fixed to the chuck table 100.

At this time, the raised pattern 3 is formed on the workpiece 1, thus, the height difference on the front surface protection sheet 10 between the inner part of the workpiece 1 and the outer circumference part of the workpiece 1 is reduced. Therefore, even when suction is carried out, the workpiece 1 is suctioned to the chuck table 100 without barely causing deformation to the outer circumference part of the workpiece 1.

After the workpiece 1 is fixed to the chuck table 100, for example, the back surface 1b of the workpiece 1 is ground using a grinding wheel or so. The thickness of the workpiece after back grinding is, for example, about 25 μm or thicker and 600 μm or thinner.

When suction is released after grinding, the workpiece 1 and the front surface protection sheet 10 is released from the chuck table 100. In the present embodiment, as Step A is performed during Step 1, as shown in FIG. 5(C), the thickness of the workpiece 1 is roughly the same from the inner part to the outer circumference part. As a result, TTV of the workpiece 1 after grinding is reduced to small amount.

### (1.6. Step 3)

In the present embodiment, preferably, the front surface protection sheet is released from the workpiece of after back grinding. That is, a processing method according to the present embodiment preferably has a step of releasing the front surface protection sheet from the workpiece of after back grinding (Step 3). For example, Step 3 is carried out as described in below.

In the case that the adhesive layer of the front surface protection sheet is formed using the energy ray-curable adhesive agent, the adhesive layer is cured and contracted by irradiating the energy ray to decrease the adhesive force against the target (workpiece). Then, a pickup tape is adhered on the back surface of the workpiece of after back grinding, and the position and the direction are adjusted so that pickup can be done. At this time, a ring frame which is placed at the outer circumference of the workpiece is also adhered to the pickup tape, and the outer circumference part of the pickup tape is fixed to the ring frame. The pickup tape may be adhered to the workpiece and to the ring frame at the same time or at different timing. Next, the front surface protection sheet is released from the workpiece which is kept held by the pickup tape.

In the present embodiment, when the front surface protection sheet is released, at least part of the raised pattern formed on the front surface of the workpiece is released together with the front surface protection sheet, and particularly preferably the entire raised pattern is released.

By releasing at least part of the raised pattern together with the front surface protection sheet, the raised pattern can be easily released from the front surface of the workpiece.

Also, a processing method of the workpiece according to the present embodiment can be applied to DBG or LDBG. In such case, the front surface protection sheet 10 shown in FIG. 4B is preferably used as the front surface protection sheet. The front surface protection sheet 10 shown in FIG. 4B has a configuration that a buffer layer 14 formed on a main plane 11b of the base 11 which is an opposite main surface to which the adhesive layer 13 is formed.

The buffer layer is a soft layer compared to the base, and prevents cracking and chipping of the workpiece by relieving stress caused to the workpiece during back grinding. Also, by having the buffer layer, the workpiece can be appropriately held to the chuck table.

A thickness of the buffer layer is preferably within a range between 1 to 200 μm, more preferably within a range between 10 to 100 μm, and even more preferably 20 to 80 μm. By making the thickness of the buffer layer within such range, stress during back grinding can be appropriately relieved by the buffer layer.

The buffer layer may be a layer formed by a buffer layer composition which includes an energy ray-polymerizable compound; or it may be a film such as a polypropylene film, an ethylene-vinyl acetate copolymer film, an ionomer resin film, an ethylene-(meth)acrylate copolymer film, ethylene-(meth)acrylate ester copolymer film, an LDPE film, an LLDPE film, etc.

In the case that the processing method of the workpiece according to the present embodiment is used to DBG or LDBG, in addition to the above-mentioned Steps 1 to 3, another step (Step 4) is included which forms grooves from the front surface side of the workpiece or forms a modified area in the workpiece from the front surface or the back surface of the workpiece.

In the case of forming the modified area to the workpiece, preferably Step 1 (and Step A) is performed before Step 4. In the case of forming the grooves by dicing or so on the front surface of the workpiece, Step 1 (and Step A) is carried out after Step 4. That is, in Step 1, the front surface protection sheet is adhered on the front surface of the workpiece with the grooves formed during Step 4 which is described in below.

In Step 4, the grooves are formed from the front surface side of the workpiece. Alternatively, the modified area is formed in the workpiece from the front surface or the back surface of the workpiece.

The grooves formed in this step is shallower than the thickness of the workpiece. The grooves can be formed by carrying out dicing process using a conventionally known dicing machine. Also, the workpiece is divided into a plurality of chips along the grooves by back grinding during the above-mentioned Step 3.

Also, the modified area is a part which has been weakened in the workpiece, and due to grinding of the grinding step, because the workpiece is thinned and force from grinding is applied, the modified area functions as a starting point of the separation into chips. That is, the grooves and the modified area in Step 4 are formed along dividing lines which separate the workpiece into chips during the above-mentioned Step 3.

The modified area is formed by irradiating laser adjusting the focus on inside the workpiece, and thereby, the modified area is formed inside of the workpiece. The laser may be irradiated from the front surface side or from the back surface side of the workpiece. Note that, regarding the embodiment of forming the modified area, in the case that the laser is irradiated from the front surface of the workpiece by performing Step 4 after Step 1, the laser is irradiated to the workpiece via the front surface protection sheet.

In DBG, back grinding of Step 2 is carried out until it reaches at least to the bottom of the grooves. Due to this back grinding, the grooves turn into cuts which penetrate through the workpiece, and the workpiece is divided and separated into individual chips.

In LDBG, the ground surface (back surface of the workpiece) formed by grinding may reach to the modified area, however, it does not have to actually reach the modified area. That is, it may be ground to the position near the modified area so that the workpiece can break from the modified area and be separated into chips. For example, the actual separation into chips may be carried out by adhering the below described pickup tape and then stretching the pickup tape.

Also, after completing back grinding, dry polishing may be carried out prior to pickup of the chips.

Step 3 may be carried out as described in above, and the front surface protection sheet is released from the separated workpieces. Even in such case, damages to the separated workpieces can be reduced.

A shape of the separated chip (separated workpiece) obtained through Step 2 may be a square, or it may be an elongated shape such as rectangle or so. Also, a thickness of the separated chip is not particularly limited, and preferably it is within a range of 5 to 100 μm, and more preferably 10 to 45 μm. According to LDBG, it becomes easier for the separated semiconductor chip to have a thickness of 50 μm or thinner, more preferably within a range between 10 and 45 μm. A size of the separated chip is not particularly limited, and preferably the chip size is smaller than 600 mm², more preferably smaller than 400 mm², and more preferably smaller than 120 mm².

According to the processing method of the workpiece according to the present embodiment, by carrying out Step A during Step 1, TTV of the workpiece after back grinding can be reduced.

Hereinabove, the embodiment of the present invention has been described, however, the present invention is not limited to the above-mentioned embodiment, and various modifications may be done within the scope of the present invention.

### EXAMPLES

In below, the present invention is explained in further detail using examples, however, the present invention is not limited to these examples.

A measuring method and an evaluation method used in the present examples are as described in below.

### (Shear Storage Modulus and Loss Tangent of Intermediate Layer)

The below described intermediate layer composition was coated by a knife method on a PET releasing film (SP-PET 382150, thickness 38 μm, made by LINTEC Corporation) so that the thickness of the coated intermediate layer composition was 400 μm, and thereby, an intermediate layer composition layer was formed. Next, using a PET releasing film (SP-PET 381130, thickness 38 μm, manufactured by LINTEC Corporation), the obtained intermediate layer composition layer was laminated to block oxygen from the intermediate layer composition layer. Next, after ultraviolet ray irradiation under the conditions of illuminance of 80 mW/cm² and irradiation dose of 200 mJ/cm² using a high-pressure mercury lamp, the intermediate layer composition layer was cured by irradiating ultraviolet ray under the conditions of illuminance of 330 mW/cm² and irradiation dose of 1260 mJ/cm² using a metal halide lamp, and thereby, the intermediate layer with a thickness of 400 μm was obtained. By stacking this intermediate layer, a sample of about 0.8 mm for measurements of shear storage modulus and loss tangent was made.

The shear storage modulus (G′) and the loss tangent (tan δ) were measured using a viscoelasticity measuring apparatus (Rheometer MCR302 made by Anton Paar GmbH). The measuring conditions were as described in below. The sample was held between parallel plates from top and bottom, and shear stress was applied to the sample under the conditions at a temperature range between 0 to 100° C., a gap of 1 mm, strain between 0.05 to 0.5%, and an angular frequency of 1 Hz for measurement. From each value, the shear storage modulus (G′) and the loss tangent (tan δ) at 65° C. were calculated. Results are shown in Table 1.

### (Shear Storage Modulus of Raised Pattern)

A sample for measuring the shear storage modulus of the raised pattern was made using the same method as in the case of the sample for measuring the shear storage modulus of the intermediate layer, except that, the below described energy ray-curable resin was coated, and after coating, the energy ray-curable resin was cured by irradiating ultraviolet ray for one time under the conditions of illuminance of 150 mW/cm² and irradiation dose of 400 mJ/cm² using a high-pressure mercury lamp. Also, other than calculating the shear storage modulus (G′) at 23° C., the shear storage modulus of the raised pattern was measured under the same conditions as in the case of the shear storage modulus of the intermediate layer. The results are shown in Table 1.

### (1) Raised Pattern

As a material for forming the raised pattern, the energy ray-curable resin shown in below was used.

### (Energy Ray-Curable Resin A)

The energy ray-curable resin A was obtained by blending 40 parts by mass of bifunctional polyol-modified urethane acrylate (molecular weight of 7300), 60 parts by mass of isobornyl acrylate, and 0.5 parts by mass of a photopolymerization initiator (OmniRad 1173, manufactured by iGM Resins).

### (Energy Ray-Curable Resin B)

The energy ray-curable resin B was obtained by blending 55 parts by mass of bifunctional polyol-modified urethane acrylate (molecular weight of 7300), 45 parts by mass of isobornyl acrylate, and 0.5 parts by mass of a photopolymerization initiator (OmniRad 1173, manufactured by iGM Resins).

### (Energy Ray-Curable Resin C)

The energy ray-curable resin C was obtained by blending 70 parts by mass of bifunctional polyol-modified urethane acrylate (molecular weight of 7300), 30 parts by mass of isobornyl acrylate, and 0.5 parts by mass of a photopolymerization initiator (OmniRad 1173, manufactured by iGM Resins).

### (2) Front Surface Protection Sheet

As the front surface protection sheet, below described front surface protection sheets were used.

### (Front Surface Protection Sheet A)

The intermediate layer composition was obtained by blending 3.4 parts by mass of a photopolymerization initiator (OmniRad 1173, manufactured by iGM Resins) and 1.0 part by mass of a chain transfer agent (Karenz MT PE1, manufactured by Resonac Holdings Corporation) to a total of 100 parts by mass of, 48 parts by mass of urethane acrylate oligomer (CN9021 NS, manufactured by Arkema), 26 parts by mass of isobornyl acrylate, 16 parts by mass of trimethylcyclohexyl acrylate, and 10 parts by mass of lauryl acrylate.

The obtained intermediate layer composition was coated using a knife method on a PET film (a thickness of 75 μm made by Toray Industries, Inc.) as a base so that the thickness of the coated intermediate layer composition was 400 μm, and thereby, the intermediate layer composition layer was formed. A PET-based releasing film (SP-PET 752150, thickness 75 μm, manufactured by LINTEC Corporation) was further laminated on the intermediate layer composition layer immediately after coating was done. Then, using a high-pressure mercury lamp, ultraviolet ray was irradiated under the conditions of illuminance of 120 mW/cm² and irradiation dose of 240 mJ/cm², and then ultraviolet ray was irradiated under the conditions of illuminance of 330 mW/cm² and irradiation dose of 1260 mJ/cm² using a metal halide lamp. Thereby, the intermediate layer composition layer was cured, and formed the intermediate layer having a thickness of 400 μm on a PET film as a base.

Next, an acrylic copolymer obtained by copolymerizing 80 parts by mass of 2-ethylhexyl acrylate (2EHA) and 20 parts by mass of 2-hydroxyethyl acrylate (HEA) were reacted with 2-isocyanatoethyl methacrylate (MOI) at an addition rate of 80 equivalents relative to hydroxyl groups derived from HEA (100 equivalents) to obtain an energy ray-curable acrylic copolymer (a weight average molecular weight: 800,000). To 100 parts by mass of the energy ray-curable acrylic copolymer, 1.5 parts by mass of trimethylolpropane adduct toluene diisocyanate (Coronate L, manufactured by Tosoh) as a crosslinking agent and 2.2 parts by mass of 2,2-dimethoxy-2-phenylacetophenone (Omnirad 651, manufactured by iGM Resins) as a photopolymerization initiator were added, and then, toluene was further added to adjust a solid concentration to 30%. Then, stirring was carried out for 30 minutes to prepare an adhesive agent composition.

Next, a solution of the prepared adhesive agent composition was coated on the PET-based releasing sheet (SP-PET382150, thickness of 38 μm made by LINTEC Corporation), and then it was dried. Thereby, an adhesive layer having a thickness of 10 μm was formed to obtain the adhesive sheet.

The releasing film of the intermediate layer obtained in above was removed, and the intermediate layer and the adhesive layer of the adhesive sheet were adhered. Thereby, a front surface protection sheet A having a configuration of base/intermediate layer/adhesive layer was produced.

### (Front Surface Protection Sheet B)

A surface protection sheet B having a configuration of base/intermediate layer/adhesive layer was produced using the same method as in the case of the surface protection sheet A, except that an intermediate layer composition was obtained by blending 48 parts by mass of urethane acrylate oligomer (CN9021 NS manufactured by Arkema), 36 parts by mass of isobornyl acrylate, 16 parts by mass of trimethylcyclohexyl acrylate, 3.4 parts by mass of a photopolymerization initiator (Omnirad 1173 manufactured by iGM Resins), and 1.0 part by mass of a chain transfer agent (Kurenz MT PE1 manufactured by Resonac Holdings Corporation) was used.

### Example 1

Regarding a wafer with bump electrodes (thickness 720 μm) having a bump electrode height of 250 μm and a pitch of 500 μm, using a dispenser (shotmaster 350DS manufactured by Musashi Engineering, Inc.), the energy ray-curable resin A with a thickness of 100 μm and a width of 4 mm was coated on an outer circumference part where the bump electrodes were not formed so that no space was formed between the outer edge of the wafer. After coating was done, ultraviolet ray was irradiated to the energy ray-curable resin A using a high-pressure mercury lamp under the conditions of illuminance of 150 mW/cm² and irradiation dose of 400 mJ/cm². Thereby, the energy ray-curable resin A was cured and a raised pattern was formed.

A tape laminator (RAD-3510F/12 manufactured by LINTEC Corporation) was used to the wafer with the raised pattern, and the front surface protection sheet A was adhered under the condition of a laminate table temperature at 65° C. After adhering, an evaluation of a bump electrode embedding property shown in below was carried out.

The wafer, to which the front surface protection sheet A had been adhered, was placed on a chuck table so that the front surface protection sheet A contacted the chuck table, and the wafer was fixed to the chuck table by suction. Next, the back surface of the wafer was ground using a grinding wheel, and grinding was stopped when the thickness of the wafer reached 300 μm. After grinding was done, an evaluation of TTV shown in below was carried out.

### (Evaluation of Bump Electrode Embedding Property)

After adhering the front surface protection sheet, the boundary between the bump electrodes and the front surface protection sheet was visually observed, and then, it was evaluated whether the front surface protection sheet did not follow the bump electrodes and formed voids. Results are shown in Table 1.
◯: No void
x: Void confirmed

### (TTV Evaluation of Wafer Outer Circumference Part After Grinding)

Regarding an area 15 mm to the inside from the edge of the wafer which was ground, a thickness of the wafer was measured using a digital microscope (VHX-7000 manufactured by KEYENSE CORPORATION). Then, the maximum height and the minimum height were selected to calculate the difference. This measurement was carried out to 4 positions (the positions of the wafer rotated by) 90° which were top, bottom, right, and left of the ground wafer, and the average of differences between the maximum heights and the minimum heights was calculated. Results are show in Table 1.

### (Evaluation of Releasing Property of Front Surface Protection Sheet and Raised Pattern)

Using a dispenser (shotmaster 350DS manufactured by Musashi Engineering, Inc.) to a 12-inch mirror wafer, the energy ray-curable resin was coated so that the thickness was as shown in Table 1 and the width was 4 mm while ensuring no space was formed between the wafer and the outer edge. After coating, ultraviolet ray was irradiated to the energy ray-curable resin for curing, and thereby, the raised pattern was formed.

A tape laminator (RAD-3510F/12 manufactured by LINTEC Corporation) was used to the mirror wafer to which the raised pattern was formed, and then, the front surface protection sheet was adhered under the condition of the laminate table temperature of 65° C. After adhering the front surface protection sheet, ultraviolet ray was irradiated (illuminance of 230 mW/cm² and irradiation dose of 1200 mJ/cm²) using a tape remover (RAD-3010F/12 manufactured by LINTEC Corporation), and releasing was carried out at a speed of 2 mm/sec. Then, the released conditions of the front surface protection and the raised pattern were evaluated. Results are shown in Table 1.
◯: Front surface protection sheet was able to be removed, and no resin was left on the wafer.
Δ: Front surface protection sheet was able to be removed, however, some resin was left on the wafer.
x: Unable to remove the front surface protection sheet.

### Examples 2 to 6 and Comparative Example 2

Back grinding of the wafer with the bump electrodes and evaluations were carried out using the same methods as in the case of Example 1; except that a sheet shown in Table 1 was used as the front surface protection sheet, a resin shown in Table 1 was used as the energy ray-curable resin forming the raised pattern, and a height of the bump electrode was set to a value show in Table 1. Results are shown in Table 1.

### Example 7

Back grinding of the wafer with the bump electrodes and evaluations were carried out using the same methods as in the case of Example 1; except that Example 7 used a wafer having a thickness of a 720 μm and also having the bump electrodes with a bump electrode height of 100 μm and a pitch of 500 μm, a sheet shown in Table 1 was used as the front surface protection sheet, a resin shown in Table 1 was used as the energy ray-curable resin forming the raised pattern, and a height of the raised pattern was set to a value show in Table 1. Results are shown in Table 1.

### Example 8

Using a dicing machine (DFD 6361 made by DISCO Corporation), grooves with a depth of 250 μm from a wafer front surface were formed to a wafer having a thickness of 720 μm and the bump electrodes with a bump electrode height of 100 μm and a pitch of 500 μm. Further, using a dispenser (shotmaster 350DS manufactured by Musashi Engineering, Inc.), the energy ray-curable resin was coated so that the thickness was as shown in Table 1 and the width was 4 mm while ensuring no space was formed between the outer edge and the inner part of the wafer. After coating was completed, ultraviolet ray was irradiated under the conditions of illuminance of 150 mW/cm² and irradiation dose of 400 mJ/cm² using a high-pressure mercury lamp to cure the energy ray-curable resin, and thereby, the raised pattern was formed.

A tape laminator (RAD-3510F/12 manufactured by LINTEC Corporation) was used to the mirror wafer to which the raised pattern was formed, and then, the front surface protection sheet A was adhered under the condition of the laminate table temperature of 65° C.

The wafer, to which the front surface protection sheet A was adhered, was placed on a chuck table so that the front surface protection sheet A contacted the chuck table, and the wafer was fixed to the chuck table by suction. A wafer backside grinder (DGP8760 made by DISCO Corporation) was used to grind the back surface of the wafer, and grinding was stopped when the thickness of the wafer reached 200 μm. Then, without releasing the front surface protection sheet A, corner edges of the separated chips were observed from the ground surface of the wafer using a digital microscope (VHX-1000 made by KEYENSE CORPORATION), and presence of cracks on each chip were verified. The number of chips with a crack among 200 chips were evaluated. In the present example, preferably the number of chips with cracks are 0.

### Comparative Example 1

Back grinding of the wafer with the bump electrodes and evaluation were carried out by the same methods as in the case of Example 1, except that a sheet shown in Table 1 was used as the front surface protection sheet, and a raised pattern was not formed. Results are shown in Table 1.

TABLE 1

| | Front surface | | | | | | | | | | | | |
|---|---|---|---|---|---|---|---|---|---|---|---|---|---|
| | protection sheet | | | Raised pattern | | | | | | Evaluation | | | |
| | | Intermediate | | Energy ray- | | | | | | Outer | | | |
| | | layer | | curable resin | | | | | Wafer | circum- | | | |
| | | Storage | | | Storage | | | | Height | ference | | | |
| | | modulus | Loss | | modulus | | | | of bump | part of | | | |
| | | G′ at | tangent | | G′ at | | Height | | electrode | wafer | Bump | | |
| | | 65° C. | tan δ | | 23° C. | Hb/ | H1 | Hb/ | Hb | T.T.V. | embedding | Releasing | Cracks |
| | Type | (MPa) | (—) | Type | (MPa) | 8 | (μm) | 1.5 | (μm) | (μm) | property | property | (number) |
| Example 1 | A | 0.016 | 0.93 | A | 90 | 31.3 | 120 | 166.7 | 250 | 10 | ◯ | ◯ | — |
| Example 2 | A | 0.016 | 0.93 | A | 90 | 31.3 | 70 | 166.7 | 250 | 39 | ◯ | ◯ | — |
| Example 3 | A | 0.016 | 0.93 | A | 90 | 31.3 | 150 | 166.7 | 250 | 30 | ◯ | ◯ | — |
| Example 4 | A | 0.016 | 0.93 | B | 60 | 31.3 | 120 | 166.7 | 250 | 12 | ◯ | ◯ | — |
| Example 5 | A | 0.016 | 0.93 | C | 15 | 31.3 | 120 | 166.7 | 250 | 11 | ◯ | ◯ | — |
| Example 6 | B | 0.2 | 1.4 | A | 90 | 31.3 | 120 | 166.7 | 250 | 10 | ◯ | ◯ | — |
| Example 7 | A | 0.016 | 0.93 | A | 90 | 12.5 | 20 | 66.7 | 100 | 5 | ◯ | ◯ | — |
| Example 8 | A | 0.016 | 0.93 | A | 90 | 31.3 | 120 | 166.7 | 250 | 10 | ◯ | ◯ | 0 |
| Comparative | A | 0.016 | 0.93 | — | — | 31.3 | 0 | 166.7 | 250 | 58 | ◯ | ◯ | — |
| example 1 | | | | | | | | | | | | | |
| Comparative | A | 0.016 | 0.93 | A | 90 | 31.3 | 250 | 166.7 | 250 | 113 | ◯ | ◯ | — |
| example 2 | | | | | | | | | | | | | |

According to Table 1, in the case of performing back grinding to the wafer with the bump electrodes to which the front surface protection sheet was adhered, by forming the raised pattern with appropriate height in accordance with the height of the bump electrodes, it was confirmed that TTV of the wafer after the back grinding can be reduced.

### REFERENCE SIGNS LISTS

1 . . . Workpiece
2 . . . Bump electrodes
3 . . . Raised pattern
10 . . . Front surface protection sheet
11 . . . Base
12 . . . Intermediate layer
13 . . . Adhesive layer
14 . . . Buffer layer

1. A processing method, comprising:
adhering a front surface protection sheet on a front surface of a workpiece having the front surface and a back surface;
grinding the back surface of the workpiece on which the front surface protection sheet is adhered;
wherein the front surface of the workpiece has bump electrodes,
a raised pattern has been formed along an outer circumference part on the front surface of the workpiece which is an area different from an area where the bump electrodes are formed when adhering the front surface protection sheet,
the front surface protection sheet is adhered on the front surface of the workpiece so as to embed the bump electrodes, and
a height Hb of each of the bump electrodes and a height H1 of the raised pattern satisfy Hb/8<H1<Hb/1.5.

2. The processing method according to claim 1, wherein the raised pattern is configured of a resin.

3. The processing method according to claim 1, wherein the area different from the area where the bump electrodes are formed includes an area where the raised pattern is not formed.

4. The processing method according to claim 1, wherein the raised pattern is formed by taking space from an outer edge of the workpiece.

5. The processing method according to claim 1, wherein the front surface protection sheet has a configuration that a base, an intermediate layer, and an adhesive layer are stacked in this order.

6. The processing method according to claim 5, wherein a shear storage modulus at 65° C. of the intermediate layer is 0.5 MPa or less.

7. The processing method according to claim 5, wherein a loss tangent at 65° C. of the intermediate layer is greater than 0.5.

8. The processing method according to claim 1 further comprising:
releasing the front surface protection sheet from the front surface after the back surface is ground;
wherein at least part of the raised pattern is released from the front surface of the workpiece when the front surface protection sheet is released.

9. The processing method according to claim 1 further comprising:
forming a groove on the front surface of the workpiece before adhering the front surface protection sheet on the front surface of the workpiece;
wherein the workpiece is separated into a plurality of separated workpieces using the groove as a starting point while grinding the back surface of the workpiece.

10. The processing method according to claim 1 further comprising:
forming a modified area in the workpiece before grinding the back surface of the workpiece;
wherein the workpiece is separated into a plurality of separated workpieces using the modified area as a starting point while grinding the back surface of the workpiece.
